(19) United States
(12) Patent Application Publication
(10) Pub. No.: US 2026/0209941 A1
(43) Pub. Date: Jul. 23, 2026

(54) GAS INLET FOR A CVD REACTOR

(71) Applicant: AIXTRON SE, Herzogenrath (DE)

(72) Inventors: Levin David Richard Johannes BEE, Hauset (BE); Marcel KOLLBERG, Würselen (DE)

(21) Appl. No.: 19/157,815

(22) PCT Filed: Feb. 23, 2024
(86) PCT No.: PCT/EP2024/054625

§ 371 Date: Aug. 19, 2025

(30) Foreign Application Priority Data
Feb. 24, 2023 (DE) 10 2023 104 548.2

(51) Int. Cl. C23C 16/455

(52) U.S. Cl. CPC C23C 16/45561

(57) ABSTRACT

A device for feeding a process gas into a process chamber of a CVD reactor includes a gas distribution body with a central region in which an opening of a gas supply line is arranged, the opening extending only over a partial circumference of the outer side of the gas supply line. The gas distribution body includes flow barriers having an inner side and an outer side and a plurality of gas passage channels which are identical to one another and evenly distributed over the circumference of the flow barrier. To reduce manufacturing tolerances, the gas passage channels are longer than the distance, measured in the radial direction, between the inner and outer side. The passage channels each have an inlet channel which branches into at least two branch channels, which each continue into an outlet channel that opens out in the outer side of the flow barrier.

### RELATED APPLICATIONS

This application is a National Stage under 35 USC 371 of and claims priority to International Application No. PCT/EP2024/054625, filed 23 Feb. 2024, which claims the priority benefit of DE Application No. 10 2023 104 548.2, filed 24 Feb. 2023.

### FIELD OF THE INVENTION

The invention relates to a device for feeding a process gas into a process chamber of a CVD reactor, with at least one gas distribution body arranged around an axis, which has a central region with an outer side surrounding the axis, in which an opening of a gas supply line extending only over a partial circumference of the outer side is arranged, with a flow barrier having an inner side facing a gas distribution chamber and an outer side facing away therefrom, with a plurality of gas passage channels connecting the inner side to the outer side, having the same design and distributed evenly around the circumference of the flow barrier for the even distribution of the process gas emerging from the opening and spreading in the gas distribution chamber into the process chamber.

### BACKGROUND

A species-related device is described in WO 2020/109361 A2. Several substantially uniformly designed gas distribution bodies are arranged vertically one above the other. In a central region of each gas distribution body, gas supply lines arranged around an axis extend in the circumferential direction, wherein each of the gas supply lines supplies one of the gas distribution bodies with a process gas which is fed into a process chamber of a CVD reactor in which the device is arranged. The gas supply line opens into a gas distribution chamber surrounding the central region. The opening of the gas supply line is arranged eccentrically—relative to the axis—in an outer wall of the central region, which is adjacent to the gas distribution chamber. The device has an outer wall with a plurality of gas passage channels distributed evenly around its outer cylinder wall, through which the process gas can enter the process chamber. In order to homogenize the process gas flow, at least one flow barrier having gas passage channels is provided there between the outer wall and the central region.

Such a device is used as a gas inlet element in a CVD reactor in order to feed various process gases into the process chamber of the CVD reactor at different vertical heights, wherein these gases flow through the process chamber in a radial direction and are led out of the CVD reactor through a gas outlet element. Several substrates are disposed in a circular arrangement around the center of the gas inlet element located in the center of the process chamber. The formation of a homogeneous process gas flow that flows evenly into the process chamber around the entire circumference of the gas inlet element requires an even distribution of the process gas emerging from the opening of the gas supply line in the one or more gas distribution chambers in the gas inlet element. For this purpose, it is advantageous if the gas passage channels of a flow barrier or the outer wall have a very small cross-sectional area so that a sufficiently high pressure drops across the gas passage channels. However, it is difficult in terms of production technology to manufacture reproducible gas passage channels with very small cross-sectional areas. The smaller the cross-sectional areas, the greater the relative deviations. Moreover, there is the problem that the cross-sections of the gas passage channels can change due to parasitic deposits of reaction products of the process gases.

DE 100 64 944 A1 describes a CVD reactor with a gas inlet element which has a gas outlet wall with gas outlet bores running obliquely to the radial direction.

KR 101487410 B1 describes a gas inlet device for generating a straight process gas flow of a CVD reactor exiting from a flat gas outlet surface, in which a single supply line branches out several times. The multiple branches end in outlet channels of the gas outlet surface.

### SUMMARY OF THE INVENTION

The invention is based on the object of taking measures to improve the homogeneity of a process gas flow from a gas inlet element having a cylindrical gas outlet surface, into which a process gas is fed eccentrically and delivered through a plurality of gas outlet openings. The manufacturing tolerances required for this purpose should also be reduced.

The object is achieved with the invention specified in the claims, wherein the subclaims represent not only advantageous developments of the invention specified in the main claim, but also independent solutions to the object.

Firstly and essentially, a device which has at least one gas distribution body for feeding a process gas into a process chamber of a CVD reactor is suggested. The device has an axis, which may be an axis of symmetry. The gas distribution body has a central region, which is surrounded by a gas distribution chamber. In the gas distribution body, there is a gas supply line that has an opening in a wall adjacent to the gas distribution chamber body, through which opening the process gas can enter the gas distribution chamber. The central region may have an outer side that runs over a cylinder surface and in which the opening is arranged. The opening may extend only over a part of the circumference or also over the entire circumference of the cylinder surface, for example around not more than a quarter, a fifth or a sixth of the circumference. Several such openings may also be arranged one behind the other in the circumferential direction. One or more flow barriers may be arranged around the central region, the inner side of each of which adjoins an inner annular gas distribution chamber and the outer side of each of which adjoins an outer annular gas distribution chamber. The at least one flow barrier may be an outer wall, the inner side of which adjoins a gas distribution chamber and the outer side of which adjoins the process chamber. The outer side may be a cylinder surface of the gas distribution body. A further flow barrier may be arranged between the central region and the outer wall. The outer wall and the flow barriers each have a plurality of gas passage channels distributed evenly over their circumference and, optionally, also over their vertical height. The gas distribution chambers may be circular volumes that are closed at the top and bottom and are limited in the radially outward direction by the one or more flow barriers, for example the outer wall. In a preferred embodiment, a process gas is fed into an innermost gas distribution chamber through the opening arranged eccentrically to the axis. The process gas may spread in the gas distribution chamber arranged in a ring around the axis and pass through the flow barrier through the gas passage channels. The flow barrier may be surrounded by an outer gas distribution chamber. It may also be surrounded by another flow barrier, or it may be surrounded directly by the outer wall. In the outer wall, there are further gas passage channels. Gas distribution may take place in each of the one or more gas distribution chambers. The total pressure inside a gas distribution chamber is substantially the same. There is therefore a small pressure difference inside a gas distribution chamber. The pressure difference is smaller than the pressure difference between two adjacent gas distribution chambers, in particular between the pressure in the radially outermost gas distribution chamber and in the process chamber. In order to ensure that the pressure difference between the adjacent gas distribution chambers and/or between the radially outermost gas distribution chamber and the process chamber is as large as possible, or that gas is distributed as homogeneously as possible into the process chamber, it is firstly suggested that the gas passage channels are longer than the distance measured radially between the inner side and the outer side of the flow barrier. The passage channels thus no longer have the shortest length, instead they are longer than the width of the flow barrier measured radially. This increases the hydraulic resistance of the gas passage channels without having to reduce their cross-section. It may also be provided that an inlet channel of the gas passage channel is followed by a section that extends in the circumferential direction of the flow barrier. An outlet channel that adjoins this may open into the outer side of the flow barrier. The section that extends in the circumferential direction lengthens the gas passage channel that also determines the hydraulic resistance. According to a preferred variant, it is suggested that the gas passage channels of at least one inner flow barrier or of the outer wall each have an inlet channel that branches out into at least two branch channels in the interior of the flow barrier or of the outer wall, each of which continues at least indirectly into an outlet channel that opens into the outer side of the flow barrier or of the outer wall. It is provided in particular that the passage channels have sections which extend in different directions. It may be provided that the passage channels have sections that change direction several times. It is considered advantageous that a large number of gas passage channels of the same design connect two adjacent gas distribution chambers or a radially outermost gas distribution chamber to the process chamber. Due to the measure according to the invention, the free cross-sectional areas of the gas passage channels can be enlarged compared to gas inlet elements known from the prior art. The number of gas inlet channels is smaller than in the prior art, so that their cross-sectional area may be made larger. A relatively high pressure can thus drop in the gas passage channel. Since the inlet channel branches into at least two branch channels, at least twice as many openings are provided on the outer side of the pressure barrier or the outer wall as on the inner side. At least one flow barrier may be arranged between the central region and the outer wall. According to a development of the invention, it may be provided that at least two flow barriers are arranged between the central region and the outer wall. The flow barriers may be arranged in a ring around the central region. The at least one flow barrier may extend along a circular arc around the axis. The device preferably has multiple gas distribution bodies arranged vertically one above the other, the flow barriers or outer walls of which may be designed identically to each other. But the flow barriers or outer walls may also be designed differently from one another, for example they may have gas passage channels of a different shape or a different number thereof. The gas supply lines are located in the central region and are arranged offset in the circumferential direction around the axis. In each of the several gas distribution bodies, one of the gas supply lines opens at a different circumferential position. The openings of the gas supply lines of gas distribution bodies arranged one above the other are angularly offset. The gas distribution bodies have angularly offset windows that are open at the top and bottom and through which a process gas can flow, which flows into a gas distribution chamber in a gas distribution body located underneath. According to a preferred variant, the inlet channels and outlet channels have an extension direction that runs in the radial direction—relative to the axis. The branch channels can extend in the circumferential direction or in the vertical direction. They may arise substantially at right angles from the inlet channel or merge into the outlet channel at right angles. Optionally, it is provided that the inlet channels and gas passage channels arising from a gas distribution chamber are arranged offset in the circumferential direction or in the vertical direction as outlet channels or gas passage channels that open into the same gas distribution chamber. It may further be provided that, in order to extend the inlet channel or to extend the outlet channel, the inlet channel or the outlet channel has a first section that has a different direction than a second section. For example, one section may extend in a horizontal plane. A second section may extend in the vertical direction. A first section of the inlet channel extending in the radial direction may be followed by a second section extending in the vertical direction. A first section of an outlet channel extending in the vertical direction may be followed by a second section extending in the horizontal direction. The sections extending in the horizontal direction may extend in the radial direction. A device may be formed from several gas distribution bodies arranged one above the other. The gas distribution bodies may be circular disc-shaped objects with circular depressions. The circular depressions form the gas distribution volumes. The ribs flanking the circular depressions form at least one flow barrier and the outer wall. The top and bottom of the gas distribution body are substantially flat, so that when gas distribution bodies are stacked one on top of the other, the flat underside lies flat on the flat top side. According to a preferred development of a device with such design, the inlet channel, the branch channels and/or the outlet channel may be open at the top. This is advantageous for purposes of manufacturing technology. The open side of the inlet channel, the branch channels or the outlet channel is then closed off by the underside of the gas distribution body immediately above it. According to a development of the invention, it may be provided that the branch channel and/or the outlet channel is formed by sections of a volume which extends from a bottom level of the gas distribution chamber to the top of the gas distribution body. This volume may be open at the top. However, it is also possible for the volume or the channels to be open at the bottom and closed by the top of a gas distribution body arranged underneath. The volume may be U-shaped in the plan view of the top of the gas distribution body. The branch channels or the outlet channels into which the branch channels can open may be formed by the volume. The U-shape of the volume may be created by a partial body that divides the volume into two channels that either open into the process chamber or into a gas distribution chamber. The partial body may have wedge-shaped side walls that taper to a rounded tip. The rounded tip may be located in front of an opening of the inlet channel. However, the tip may also be located in front of an opening of an outlet channel if the section of the gas passage channel arranged upstream of the volume already has a branch. The inlet channel may preferably branch into three or more outlet channels. In a further development, it may be provided that an inlet channel that extends in the radial direction branches into two branch channels which extend in the circumferential direction or in the vertical direction. Both branch channels may then branch again, in which case a branch channel that extends in the horizontal direction preferably branches into further branch channels that extend in the vertical direction, or a branch channel extending vertically preferably branches into further branch channels extending horizontally. A total of four further branch channels open out to form an outlet channel in the outer side of either the flow barrier or the outer wall. The gas distribution bodies may be made of metal, graphite, a ceramic material or quartz. The at least one gas distribution body preferably consists of a single-piece quartz part, wherein the cavities and channels are produced using the SLE process. It has been found to be advantageous if at least some of the channels, for example the inlet channels, the branch channels or the outlet channels, have a rectangular or square cross-section. However, it is also provided that at least some of the channels, for example the inlet channels, the branch channels or the outlet channels, have a different, in particular circular, cross-section. It may also be provided that only one flow barrier or only the outer side in each case has gas passage channels designed according to the invention. Other flow barriers or the outer wall may then also have gas passage channels that do not branch. However, it is also provided that all gas passage channels of all flow barriers and of the outer wall have the branches according to the invention. According to the invention, the gas passage channels formed by a flow barrier or by the outer wall may be designed identically to one another. It may be provided that the total number of gas passage channels of the flow barriers arranged one behind the other in the flow direction or of the outer wall is at least doubled in each case. For example, an innermost flow barrier may have a first number of gas passage channels, each of which branches, and a second flow barrier surrounding it or an outer wall surrounding it may have at least or approximately twice the number of gas passage channels, which preferably branch again. The cross-sectional areas of the inlet channels and/or of the outlet channels may be at least 1 mm². The cross-sectional areas of the branch channels may be larger.

### BRIEF DESCRIPTION OF THE DRAWINGS

Embodiments of the invention are explained below with reference to the accompanying drawings. In the drawings:

FIG. 1 schematically shows a vertical section through a reactor housing 1 of a CVD reactor,

FIG. 2 schematically shows five gas distribution bodies 12 of a feed device 11 of a gas inlet element 9 in perspective view,

FIG. 3 is a plan view of a gas distribution body 12,

FIG. 4 is a perspective view of a section of an embodiment of a gas distribution body 12,

FIG. 5 shows the detail from FIG. 4 in plan view,

FIG. 6 shows an enlargement of the detail VI from FIG. 5 in a perspective view as a first embodiment,

FIG. 7 shows the section along line VII-VII in FIG. 5 as a second embodiment,

FIG. 8 the section along line VIII-VIII in FIG. 5,

FIG. 8a shows the section according to FIG. 8 but of a third embodiment,

FIG. 8b shows the section according to FIG. 8 but of a fourth embodiment,

FIG. 9 shows the section along line IX-IX in FIG. 5,

FIG. 10 shows the view according to arrow X in FIG. 9,

FIG. 11 is a detail in perspective of a gas distribution body 12 of a fifth embodiment,

FIG. 12 shows the plan view of the detail shown in FIG. 11,

FIG. 13 shows the section along line XIII-XIII in FIG. 12,

FIG. 14 shows the section along line XIV-XIV in FIG. 12,

FIG. 15 shows the section along line XV-XV in FIG. 12,

FIG. 16 is a plan view of a gas distribution body 12 of a sixth embodiment,

FIG. 17 shows the section along line XVII-XVII in FIG. 16,

FIG. 18 is a view in the direction of arrow XVIII in FIG. 16,

FIG. 19 is a plan view of a gas distribution body 12 of a seventh embodiment,

FIG. 20 is a perspective representation of an exploded detail of the gas distribution body 12 according to FIG. 19,

FIG. 21 enlarges section XXI in FIG. 19,

FIG. 22 shows the section along line XXII-XXII in FIG. 21,

FIG. 23 shows the section along the line XXIII-XXIII in FIG. 21,

FIG. 24 enlarges section XXIV in FIG. 19,

FIG. 25 shows the section along line XXV-XXV FIG. 24,

FIG. 26 shows the section along line XXVI-XXVI in FIG. 24,

FIG. 27 shows the section along line XXVII-XXVII in FIG. 24,

FIG. 28 is a plan view of a gas distribution body 12 of an eighth embodiment.

### DETAILED DESCRIPTION

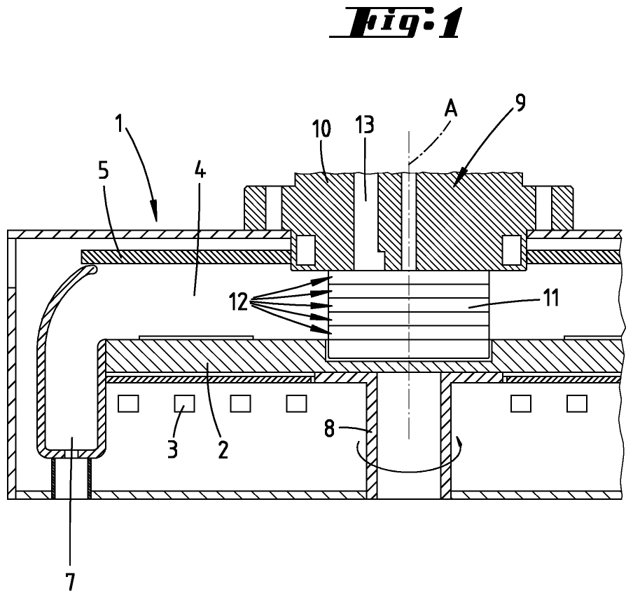

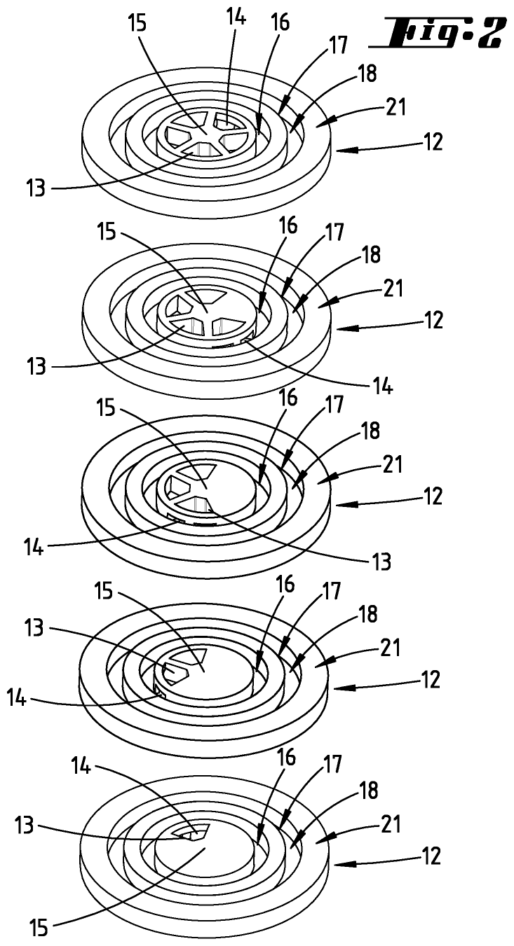

FIG. 1 is a schematic representation of a CVD reactor for depositing, for example, II-VI layers, IV-IV layers or III-III layers. Substrates are arranged in a susceptor 2, which can be coated in the process chamber 4 of the CVD reactor. The susceptor 2 has a circular disc shape and is brought to a process temperature from below by means of a heating device 3. The heating device 3 may be a resistance heater, an RF heater or an IR heater. A shaft 8 carrying the susceptor 2 may be rotated about its contour axis. In the center of the reactor housing 1 there is a gas inlet element 9, which has a feed device 11 protruding into the process chamber 4. The process chamber 4 is delimited at the bottom by the susceptor 2 and at the top by a process chamber ceiling 5. The substrates are arranged in a ring-shaped arrangement around the gas outlet surface of the feed device 11 arranged in the center of the process chamber 4. A gas outlet element 7 extends around the susceptor 2 for discharging the process gases or reaction products.

The gas inlet member 9 has a head 10 into which a plurality of gas supply lines 13 extend, which continue into gas distribution bodies 12 that form the feed device 11.

The gas distribution bodies 12 are disc-shaped quartz bodies which have a central region 15 through which the gas supply lines 13 extend. FIG. 2 shows a perspective and schematic view of five such gas distribution bodies 12 that form the feed device 11 when arranged one directly above the other. Each gas distribution body 12 has an opening 14 in which one of the gas supply lines 13 opens to a gas distribution chamber 16. A process gas can enter the gas distribution chamber 16 through the opening 14. The opening 14 may be divided into two opening sections by a baffle wall 31.

In the radially outward direction, the first gas distribution chamber 16 is adjoined by a flow barrier 17 which has gas passage channels 22 (not shown in FIG. 2) through which the process gas can flow from the inner side 17′ of the flow barrier 17 to its outer side 17″. The outer side 17″ adjoins a gas distribution volume 18 which is surrounded by an outer wall 21. The outer wall 21 has gas passage channels 24 which are evenly distributed about its circumference and through which the process gas can flow into the process chamber 4.

In other embodiments, for example in the embodiment shown in FIGS. 11 and 12, the second gas distribution volume 18 adjoins a second flow barrier 19, which has gas passage channels 23 connecting the inner side 19′ with the outer side 19″.

FIGS. 4 to 8 show an embodiment of a gas distribution body 12 which has a flow barrier 17 surrounding a radially inner gas distribution chamber 16, a radially outer gas distribution chamber 18 surrounding the flow barrier 17 and an outer wall 21. Both the flow barrier 17 and the outer wall 21 have branched gas passage channels, 22 and 24 respectively.

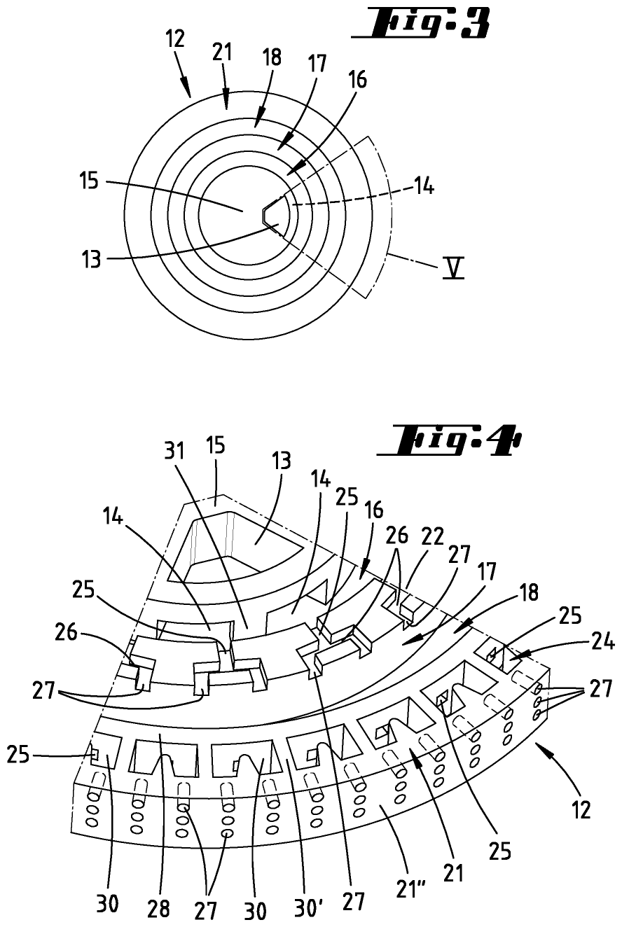

FIG. 6 shows a first embodiment of a branching gas passage channel 22. Y-shaped depressions are introduced into the top side 28 of the annular flow barrier 17. A section of the depression adjacent to the inner side 17′ forms an inlet channel 25 extending in the radial direction, which branches into two branch channels 26 extending in the circumferential direction. The inlet channels 25 of circumferentially adjacent gas passage channels 22 are evenly distributed in the circumferential direction. The branch channels 26 continue in radially extending outlet channels 27 which open into the outer side 17″ of the flow barrier 17. Adjacent outlet channels 27 are evenly spaced from one another. The angle between two adjacent outlet channels 27 is thus half the size of the angle between two adjacent inlet channels 25. The channels 25, 26, 27 are open towards the upper side 28 of the gas distribution body 12 and in the assembled state of the feed device 11 are closed by the underside 29 of a gas distribution body 12 arranged above it.

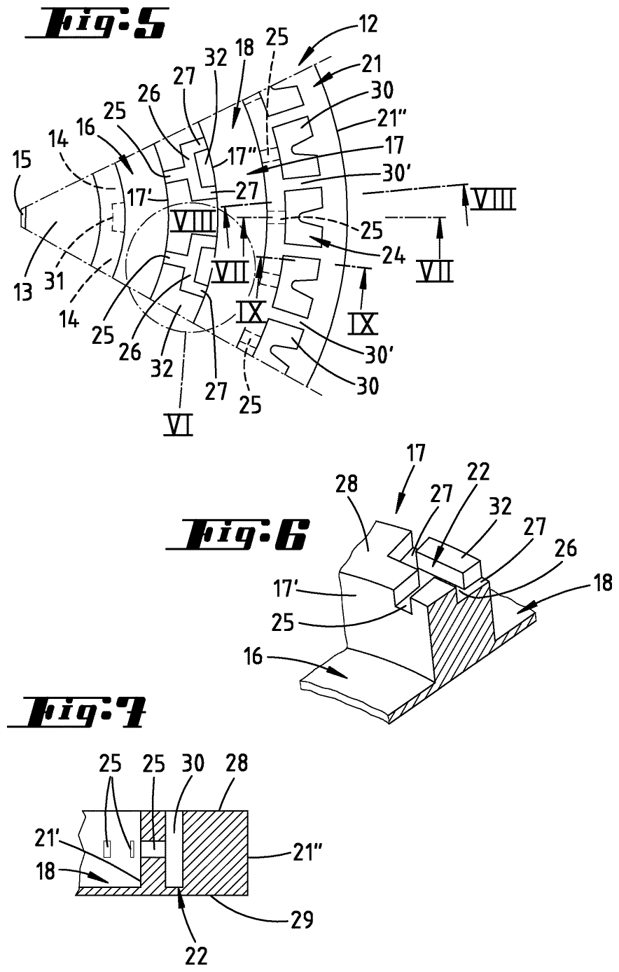

FIGS. 8, 9, 10 show a second embodiment of a branching gas passage channel 24. An inlet channel 25 with a rectangular cross-section is located approximately halfway up the inner side 21′ of the outer wall 21. The outer wall 21 forms a plurality of volumes 30 separated from one another by partition walls 34, which extend from a bottom surface of the gas distribution volume 18 to the top 28. The volumes 30 are closed at the bottom but open at the top. The inlet channel 25 opens approximately centrally into the volume 30. The volume 30 is divided into two sections by a partial body 33. These two sections each form a branch channel 26. The inlet channel 25 opens in front of a rounded front side of the wedge-shaped partial body 33. The partial body 33 forms side walls which taper towards the rounded front side and flank the branch channels.

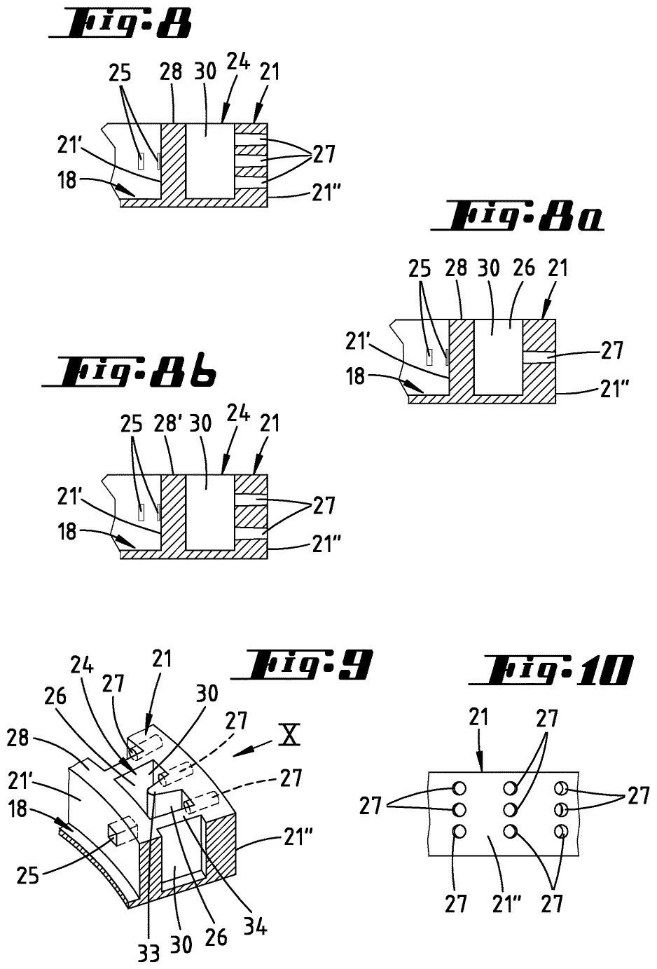

The branch channels open into outlet channels 27, which have a circular cross-section. In the embodiment shown in FIG. 10, three outlet channels 27 arranged vertically one above the other emerge from each of the branch channels 26.

In the third embodiment shown in FIG. 8a, the branch channel 26 opens into only one outlet channel 27.

In the fourth embodiment shown in FIG. 8b, the branch channel 26 opens into two outlet channels 27.

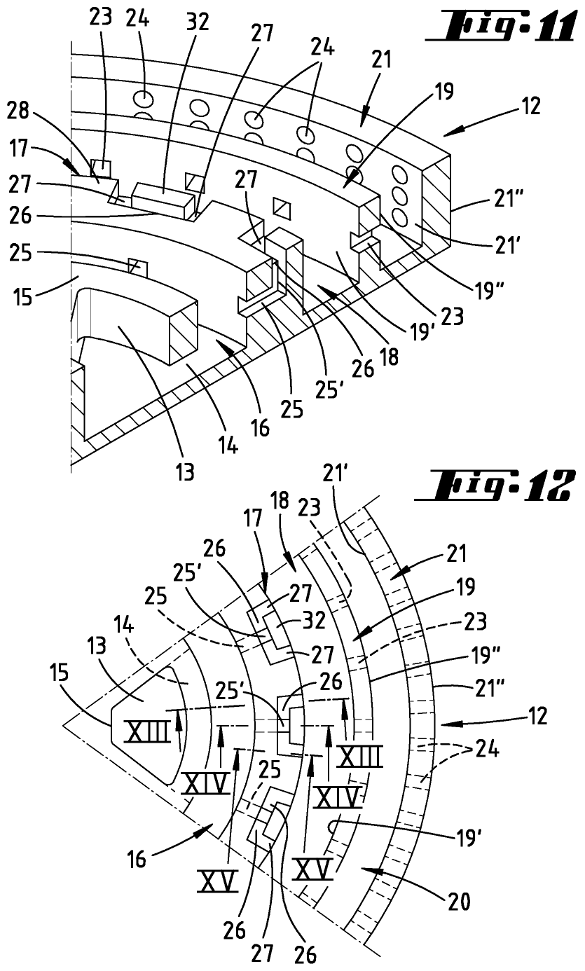

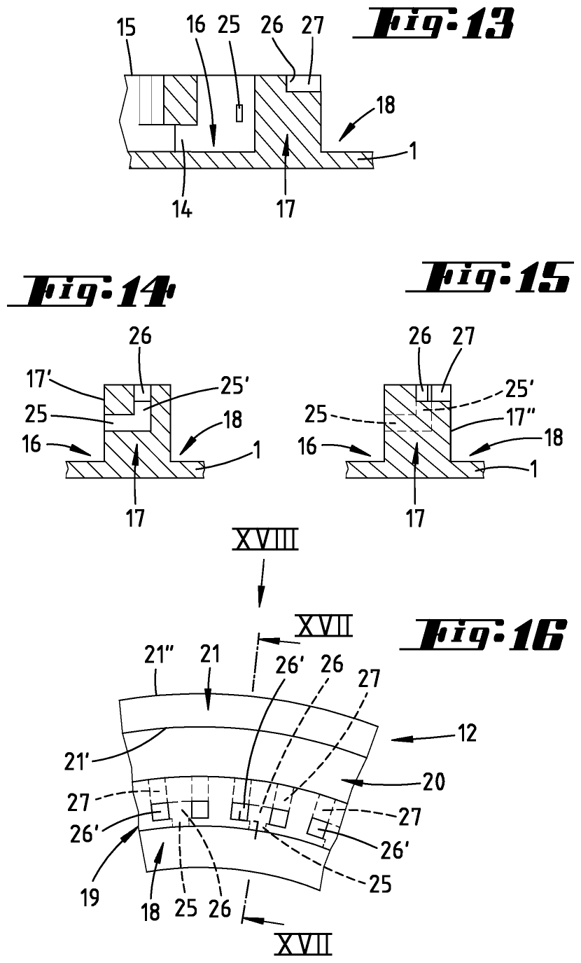

In the fifth embodiment shown in FIGS. 11 to 15, a first section 25 of an inlet channel opens into a second section 25′ of the inlet channel. While the first section 25 extends in the radial direction, the second section 25′ extends vertically upwards. There, the second section 25′ divides into two branch channels 26 extending in the circumferential direction. The two branch channels 26 each merge into an outlet channel 27 running in the radial direction. A second flow barrier 19 surrounding the flow barrier 17 has gas passage channels 23 extending in the radial direction with a square cross-section. The outer wall 21 surrounding the second flow barrier 19 has gas passage channels 24 that have a circular cross-section. While the first section 25 extends approximately halfway up the inner wall 17′, the outlet channel 27 opens into the uppermost region of the outer wall 17″. The outlet channel 27 and the branch channels 26 are open towards the upper side 28 in order to be closed by the underside 29 of the gas distribution body 12 located above it in the assembled state.

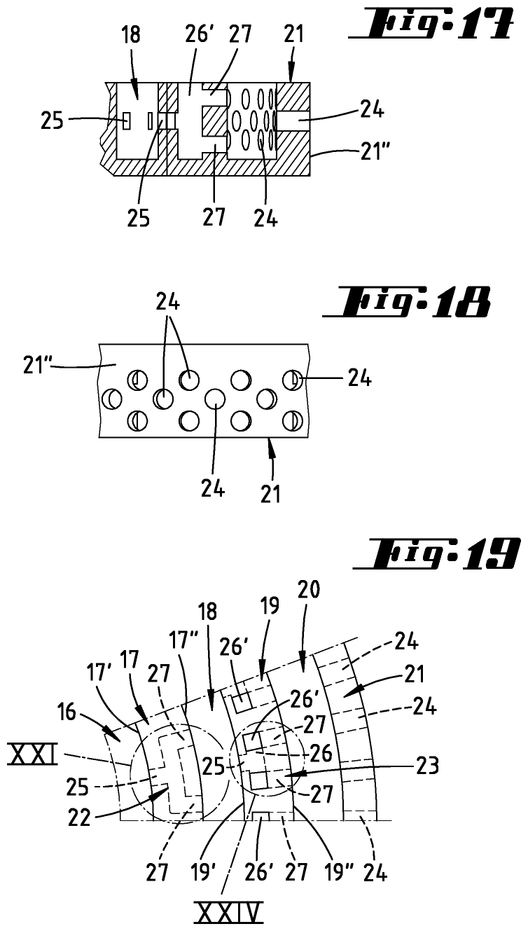

In the sixth embodiment shown in FIGS. 16 to 18, the inlet channel 25 initially branches into two first branch channels 26, which extend in a horizontal plane in the circumferential direction. The first branch channels 26 then each branch into second branch channels 26′, which extend in the vertical direction and are open at the top to be closed by the underside of the gas distribution body 12 above. The second branch channels 26′ each open into an outlet channel 27. The inlet channel 25 and the outlet channels 27 extend in the radial direction and are offset both in the vertical direction and in the circumferential direction.

The inlet channel 25 branches by 90° in one circumferential direction and by 90° in the opposite circumferential direction. The length of the branch channels 26 may be greater than a diameter of the branch channel 26. However, the length may also be less than the diameter of the branch channel. The two branch channels 26 each branch by 90° upwards and 90° downwards into the second branch channels 26′. The length of the second branch channels 26′ may also be smaller than their diameter or larger than their diameter. The second branch channels 26′ each curve by 90° into an outlet channel 27. Two outlet channels 27 are located vertically one above the other.

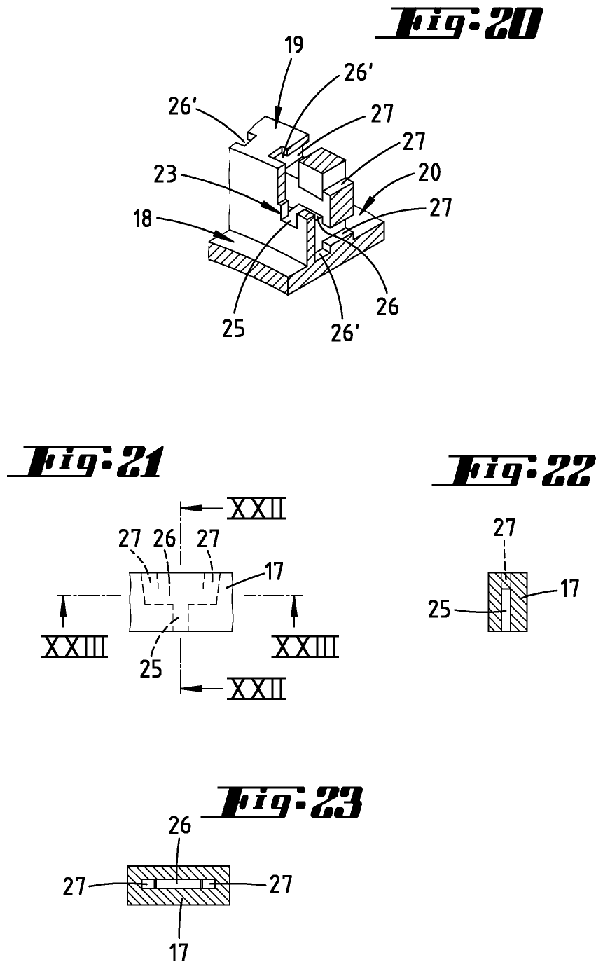

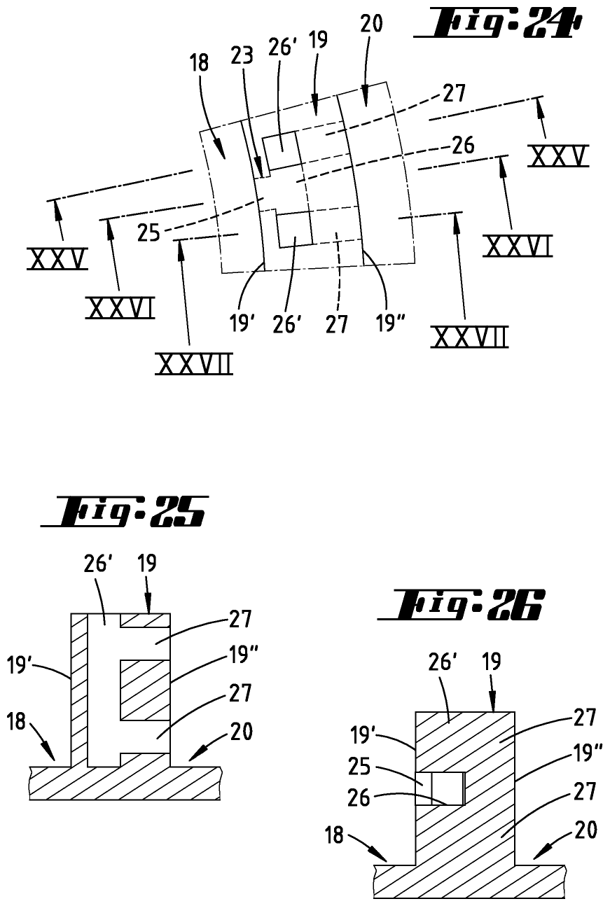

The embodiment shown in FIG. 19 has two flow barriers 17, 19, each of which has branching gas passage channels 22, 23, 24. The gas passage channels 22 of the flow barrier 17 are shown in detail in FIGS. 21 to 23. These are T-shaped branching gas passage channels 22, in which an inlet channel 25 branches into two branch channels 26, which in turn each merge into an outlet channel 27. Here, all channels 25, 26, 27 extend approximately halfway up the flow barrier 17 and lie in the same horizontal plane.

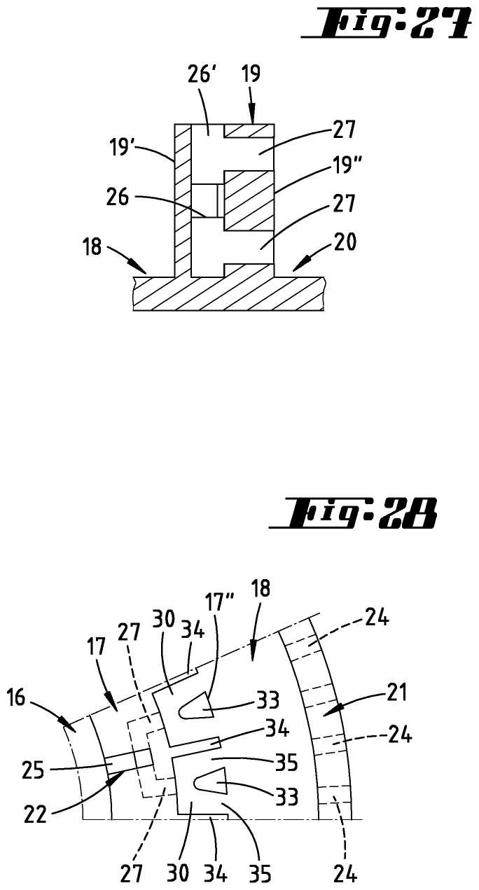

FIGS. 19 to 27 show the gas passage channels 23 of the flow barrier 19, which substantially correspond to those shown in FIGS. 16 and 17. An inlet channel 25 initially splits into two branch channels 26. These then split again into two further branch channels 26′. Each of the second branch channels 26′ opens into an outlet channel 27 in the outer side 19′.

FIG. 28 shows a further embodiment in which the flow barrier 17 initially has an inlet channel 25 that is divided into two branch channels 26, wherein the inlet channel 25 and the branch channels 26 each have a square cross-section and in particular have the same cross-section. The inlet channel 25 is again open at the top and continues into a second section 25′ running vertically downwards. The latter splits into the branch channels 26. Each of the two branch channels 26 continues into an outlet channel 27, each of which opens into a volume 30. Several volumes 30 of the same design are arranged in the circumferential direction along the outer side of the flow barrier 17. In each of the volumes 30, there is a partial body 33 which divides the volume 30 into two channels 35. A rounded front side of the partial body 33 is located in front of the opening of the outlet channel 27. The channels 35 and the volume 30 extend over the entire height of the flow barrier 17.

The gas distribution chamber 18 surrounding the flow barrier 17 adjoins an outer wall 21 which forms gas passage channels 24 which are unbranched here. However, the gas passage channels 24 of the outer wall 21 may also branch, as in the other embodiments.

In all embodiments, the gas distribution chambers 16, 18, 20 may be open all around, thus forming an annular volume. In all embodiments, the flow barriers 17, 19 may be closed all around, so that they separate the radially inner and radially outer gas distribution chambers from one another and gas exchange between the radially inner and the radially outer gas distribution chamber can only take place through the gas passage channels.

In all embodiments, the gas distribution chambers 16, 18, 20 may also have radial barriers which divide the gas distribution chambers 16, 18, 20, for example, into two half chambers.

In some embodiments, the gas passage channels 22, 23, 24 may have an inlet channel 25 extending in the radial direction, from which a section 26 diverges approximately transversely to the radial direction, which extends in the circumferential direction of the flow barrier 17, 19, 21. An outlet channel 27 may diverge approximately transversely from this section 26, which again extends in the radial direction.

The above notes are intended to explain the inventions covered by the application as a whole, which also independently develop the state of the art at least by the following combinations of features, wherein two, several or all of these combinations of features may also be combined, namely:

A device characterized in that the gas passage channels 22, 23, 24 are longer than the distance measured in the radial direction from the inner side 17′, 19′, 21′ and the outer side 17″, 19″, 21″.

A device characterized in that the gas passage channels 22, 23, 24 each have an inlet channel 25 that continues in the interior of the flow barrier 17, 19, 21 into at least one section 26, 26′ which extends in the circumferential direction and has an outlet channel 27 which opens into the outer side of the flow barrier 17, 19, 21.

A device characterized in that the gas passage channels 22, 23, 24 each have an inlet channel 25 which branches into at least two branch channels 26, 26′ in the interior of the flow barrier 17, 19, 21, wherein the branch channels 26, 26′ each continue into at least one outlet channel 27 which opens into the outer side of the flow barrier 17, 19, 21.

A device according to one of the preceding claims, characterized by a plurality of flow barriers 17, 19, 21, each of which has passage channels 22, 23, 24, wherein a radially outermost of the flow barriers 17, 19, 21 forms an outer wall 21, the outer side 21″ of which forms a cylindrical surface of the gas distribution body 12, wherein the inner side 17′ of a radially innermost flow barrier 17 of the flow barriers 17, 19, 21 adjoins a radially innermost gas distribution chamber 16, which surrounds the outer side of the central region 15, and wherein the outer side 17″ of the radially innermost flow barrier 17 adjoins a further gas distribution chamber 18, wherein at least the passage channels 22, 23, 24 of one of the flow barriers 17, 19, 21 or at least two of the flow barriers 17, 19, 21 or all of the flow barriers 17, 19, 21 each have an inlet channel 25 which branches into at least two branch channels 26, 26′ in the interior of the flow barrier 17, 19, 21.

A device characterized in that the inlet channels 25 extend radially to the axis of symmetry A, and/or that the branch channels 26 branch off from the inlet channel 25 in the circumferential direction or parallel to the direction of the axis of symmetry A.

A device characterized in that the inlet channels 25 and outlet channels 27 assigned to a gas distribution chamber 18, 20 are arranged offset from one another in the circumferential direction and/or in the direction of the axis of symmetry A.

A device characterized in that the inlet channel 25 has a first section extending in the radial direction and a second section 25′ extending in the direction parallel to the axis of symmetry A, which is adjoined by two branch channels 26 running in the circumferential direction.

A device characterized in that several gas distribution bodies 12 are located directly above one another and form gas supply lines 13 arranged eccentrically to the axis of symmetry A.

A device characterized in that the inlet channel 25, the branch channels 26 and the outlet channel 27 have a rectangular cross-section.

A device characterized in that at least one of the inlet channel 25, the branch channels 26 and the outlet channel 27 is open to one side 28 of the gas distribution body 12 and is closed from an opposite side 29 of an adjacent gas distribution body 12.

A device characterized in that the branch channels 26 are formed by a volume 30 which is U-shaped in plan view onto the top of the gas distribution body 12, wherein side walls of the U-legs converge at an acute angle in a curve.

A device characterized in that the gas passage channel 22, 23, 24 branches into three or more outlet channels 27.

A device characterized in that an outer side 17″ of the flow barrier 17 has a plurality of volumes 30 separated by partition walls 34, wherein the volume 30 is divided by a partial body 33 into two channels 35 which open into a gas distribution volume 18, and wherein the partial body 33 is arranged in front of an outlet channel 27 opening into the volume 30.

All disclosed features are essential to the invention (individually, but also in combination with one another). The disclosure content of the associated/attached priority documents (copy of the prior application) is hereby fully included in the disclosure of the application, also for the purpose of including features of these documents in claims of the present application. The subclaims characterize, even without the features of a referenced claim, with their features independent inventive developments of the prior art, in particular with the purpose of making divisional applications based on these claims. The invention specified in each claim may additionally have one or more of the features provided in the above description, in particular with reference numbers and/or specified in the list of reference numbers. The invention also relates to designs in which individual features mentioned in the above description are not implemented, in particular insofar as they are clearly dispensable for the respective intended use or can be replaced by other means with the same technical effect.

List of reference symbols

| | |
|---|---|
| 1 | Reactor housing |
| 2 | Susceptor |
| 3 | Heating device |
| 4 | Process chamber |
| 5 | Process chamber ceiling |
| 7 | Gas outlet device |
| 8 | Shaft |
| 9 | Gas inlet device |
| 10 | Head |
| 11 | Feeding device |
| 12 | Gas distribution body |
| 13 | Gas supply line |
| 14 | Opening |
| 15 | Central region |
| 16 | First gas distribution chamber |
| 17 | First flow barrier |
| 17′ | Inner side |
| 17″ | Outer side |
| 18 | Second gas distribution chamber |
| 19 | Second flow barrier |
| 19′ | Inner side |
| 19″ | Outer side |
| 20 | Third gas distribution chamber |
| 21 | Third flow barrier, outer wall |
| 21′ | Inner side |
| 21″ | Outer side |
| 22 | Gas passage channel |
| 23 | Gas passage channel |
| 24 | Gas passage channel |
| 25 | Inlet channel |
| 25′ | Section of the inlet channel |
| 26 | Branch channel, section |
| 26′ | Branch channel, section |
| 27 | Outlet channel |
| 28 | Top |
| 29 | Bottom |
| 30 | Volume |
| 31 | Baffle |
| 32 | Partition |
| 33 | Partial body |
| 34 | Partition wall |
| 35 | Channel |
| A | Axis of symmetry |

1. A device (11) for feeding a process gas into a process chamber (4) of a chemical vapor deposition (CVD) reactor, the device (11) comprising:
a first gas distribution body (12) arranged around an axis (A), the first gas distribution body (12) having:
a central region (15) with an outer side surrounding the axis (A), the central region (15) having an orifice (14) of a first gas supply line (13), the orifice (14) extending only or at least over a partial circumference of the outer side;
a first flow barrier (17, 19, 21) with an inner side (17′, 19′, 21′) pointing towards a first gas distribution chamber (16, 18, 20) of the first gas distribution body (12) and an outer side (17″, 19″, 21″) pointing away from the first gas distribution chamber (16, 18, 20); and
a first plurality of gas passage channels (22, 23, 24) connecting the inner side (17′, 19′, 21′) of the first flow barrier (17, 19, 21) with the outer side (17″, 19″, 21″) of the first flow barrier (17, 19, 21) and evenly distributed over a circumference of the flow barrier (17, 19, 21) for uniformly distributing process gas emerging from the orifice (14) and distributing the process gas in the gas distribution chamber (16, 18, 20) into the process chamber (4),
wherein the first plurality of gas passage channels (22, 23, 24) have an inlet channel with a first section (25) running in a radial direction and with a second section (25′) running in a direction parallel to the axis (A),
wherein the second section (25′) is connected to two branch channels (26) running in a circumferential direction, and
wherein each of the two branch channels (26) progresses into an outlet channel (27) running in the radial direction.

2. (canceled)

3. The device (11) of claim 1, wherein the first gas distribution body (12) further comprises a plurality of flow barriers (17, 19, 21), each of which has gas passage channels (22, 23, 24), wherein a radially outermost one of the flow barriers (17, 19, 21) forms an outer wall (21),
wherein an outer side (21″) of the outer wall (21) forms a cylinder sheath surface of the first gas distribution body (12),
wherein an inner side (17′) of a radially innermost flow barrier (17) of the flow barriers (17, 19, 21) adjoins a radially innermost gas distribution chamber (16) which surrounds an outer side of the central region (15), and
wherein an outer side (17″) of the radially innermost flow barrier (17) adjoins a further gas distribution chamber (18).

4. (canceled)

5. The device (11) of claim 1, wherein the inlet channels and outlet channels (27) are offset from one another in the circumferential direction and/or in the direction of the axis (A).

6. (canceled)

7. The device (11) of claim 1, wherein the first gas distribution body (12) is a part of a plurality of gas distribution bodies (12) that lie directly above one another and form gas supply lines (13) arranged eccentrically to the axis (A).

8. The device (11) of claim 1, wherein the inlet channels, the branch channels (26) and the outlet channels (27) each have a rectangular cross-section.

9. The device (11) of claim 1, wherein at least one of the inlet channels (25), the branch channels (26) and the outlet channels (27) is open to a top side (28) of the first gas distribution body (12) and is closed by a bottom side (29) of a second gas distribution body (12) disposed adjacent to the first gas distribution body (12).

10. (canceled)

11. The device (11) of claim 1,
wherein the two branch channels (26) are part of a volume (30) that is U-shaped in a plan view of a top side of the first gas distribution body (12), and
wherein side walls of U-legs of the volume (3) converge at an acute angle in a curve.

12. (canceled)

13. The device (11) of claim 1,
wherein the outer side (17″) of the first flow barrier (17) has a plurality of volumes (30) separated by partition walls (34),
wherein each of the volumes (30) is divided by a partial body (33) into two channels (35) which open into a second gas distribution chamber (18), and
wherein the partial body (33) is arranged in front of one of the outlet channels (27).

14. (canceled)

15. The device (11) of claim 1, wherein the first section (25) of the inlet channel extends up to half a height of the inner side (17′) of the first flow barrier (17, 19, 21), and the outlet channels (27) open in an uppermost region of the outer side (17″) of the first flow barrier (17, 19, 21).

16. The device (11) of claim 3,
wherein a radially outer flow barrier (19) surrounding the radially innermost flow barrier (17) has a second plurality of gas passage channels (23), each extending in the radial direction with a square cross-section, and
wherein an outer wall (21) surrounding the radially outer flow barrier (19) has a third plurality of gas passage channels (24), each with a circular cross-section.

17. The device (11) of claim 7, wherein the outlet channels (27) and the branch channels (26) are open to a top side (28) of the first gas distribution body (12), and the outlet channels (27) and the branch channels (26) are closed by a bottom side (29) of a second gas distribution body (12) disposed adjacent to the first gas distribution body (12).
